(19) United States
(12) Patent Application Publication
(10) Pub. No.: US 2025/0261305 A1
(43) Pub. Date: Aug. 14, 2025

(54) GLASS SUBSTRATE, MULTILAYER WIRING SUBSTRATE, AND METHOD FOR PRODUCING GLASS SUBSTRATE

(71) Applicant: TOPPAN Holdings Inc., Tokyo (JP)

(72) Inventor: Masashi SAWADAISHI, Tokyo (JP)

(73) Assignee: TOPPAN Holdings Inc., Tokyo (JP)

(21) Appl. No.: 19/094,517

(22) Filed: Mar. 28, 2025

Related U.S. Application Data
(63) Continuation of application No. PCT/JP2023/029925, filed on Aug. 21, 2023.

(30) Foreign Application Priority Data
Sep. 30, 2022 (JP) 2022-158018

(51) Int. Cl. H05K 1/03; H05K 1/02; H05K 3/00; H05K 3/40

(52) U.S. Cl. CPC H05K 1/0306; H05K 1/0298; H05K 3/0029; H05K 3/4038; H05K 2201/10734; H05K 2203/107

(57) ABSTRACT

The present invention provides a glass substrate capable of forming a through electrode with excellent adhesion. To achieve this, a glass substrate of the present invention is a glass substrate, having a first surface and a second surface, that includes at least one through hole penetrating from the first surface to the second surface, wherein a cut surface of the through hole in a thickness direction of the glass substrate has a shape of a side surface, the shape having a dispersion roughness of 1,500 nm or more and an unevenness width of 1,500 nm or more.

### CROSS-REFERENCE TO RELATED APPLICATIONS

The present application is a continuation application of International Application No. PCT/JP2023/029925, filed on Aug. 21, 2023, which is based on and claims priority to Japanese Patent Application No. 2022-158018, filed on Sep. 30, 2022, the entire contents of each are incorporated herein by reference.

### TECHNICAL FIELD

The present invention relates to a glass substrate, a multilayer wiring substrate, and a method for producing a glass substrate.

### BACKGROUND ART

Recently, three-dimensional mounting technique has been used in which circuit boards are laminated. In such a mounting technique, through electrodes are formed in the circuit board. The through electrodes are formed by forming through holes in a substrate made of an insulator and disposing conductors in the through holes. Higher integration of circuit boards also requires finer through holes.

For example, Patent Literature 1 discloses a method for forming a plurality of precision holes in a substrate by drilling, the method including: a step of affixing a sacrificial cover layer 100 to a surface of the substrate; a step of positioning a laser beam in a predetermined location relative to the substrate and corresponding to a desired location of one of the plurality of precision holes; a step of forming a through hole in the sacrificial cover layer by repeatedly pulsing the laser beam at the predetermined location; and a step of pulsing the laser beam into the through hole formed in the sacrificial cover layer.

Patent Literature 2 discloses an article including a glass-based substrate with a hole, a semiconductor package including the article with a hole, and a method for forming a hole in a substrate. The article therein includes a glass-based substrate having a first surface, a second surface, and at least one hole extending from the first surface. The at least one hole has an interior wall having a surface roughness Ra of 1 μm or less. The at least one hole has a first opening having a first diameter that is present at the first surface. A first plane is defined by the first surface of the glass-based substrate based on an average thickness of the glass-based substrate. A ratio of a depression depth to the first diameter of the at least one hole is less than or equal to 0.007.

### CITATION LIST

### Patent Literature

### Patent Literature 1

Japanese Patent Laid-Open Publication No. 2019-030909

### Patent Literature 2

Japanese Translation of PCT International Application Publication No. 2019-530629

### SUMMARY OF INVENTION

### Technical Problem

However, the techniques disclosed in Patent Literatures 1 and 2 do not discuss the relationship between the roughness of a side surface of the through hole and the adhesion of the conductive material.

For this reason, the side surface of the through hole described in Patent Literatures 1 and 2 has reduced adhesion at the interface between a conductor layer and glass, which causes the conductive layer to peel off the glass in a through electrode. This makes it difficult to prevent peeling at the interface between the conductor layer and the glass due to: thermal stress during operation after mounting the semiconductor; and stress due to the difference in a linear expansion coefficient between the conductor and the glass caused by temperature changes during operation.

It is therefore an object of the present invention to provide a glass substrate capable of forming a through electrode with excellent adhesion, and a multilayer wiring substrate including such a glass substrate.

### Solution to Problem

To solve the above-mentioned problems, one typical glass substrate of the present invention is a glass substrate, having a first surface and a second surface, that includes at least one through hole penetrating from the first surface to the second surface, wherein a cut surface of the through hole in a thickness direction of the glass substrate has a shape of a side surface, the shape having a dispersion roughness of 1,500 nm or more and an unevenness width of 1,500 nm or more.

### Advantageous Effects of Invention

According to embodiments of the present invention, it is possible to provide a glass substrate capable of forming a through electrode with excellent adhesion, and a multilayer wiring substrate including such a glass substrate.

Problems, configurations, and effects other than those described above will be made clear by the following explanation of the embodiments of the invention.

### BRIEF DESCRIPTION OF DRAWINGS

FIG. 1 is a diagram showing a cross section of an X-shaped through hole and a method for measuring inclination angles.

FIG. 2 is a diagram showing a cross section of a truncated cone-shaped through hole and a method for measuring inclination angles.

FIG. 3 is a diagram showing a method for measuring a side surface roughness of a through hole.

FIG. 4 is a diagram showing measurement results of inclination angles of a through hole of Example 1 in a second embodiment.

FIG. 5 is a diagram showing measurement results of inclination angles of a through hole of Example 2 in the second embodiment.

FIG. 6 is a diagram showing measurement results of inclination angles of a through hole of Example 3 in the second embodiment.

FIG. 7 is a diagram showing a cross-sectional shape of a through hole of Comparative Example 1 in a first embodiment.

FIG. 8 is a diagram showing measurement results of inclination angles of the through hole of Comparative Example 1 in the first embodiment.

FIG. 9 is a diagram showing a cross-sectional shape of a through hole of Comparative Example 2 in the first embodiment.

FIG. 10 is a diagram showing measurement results of inclination angles of the through hole of Comparative Example 2 in the first embodiment.

FIG. 11 is a diagram showing a cross-sectional shape of a through hole of Comparative Example 3 in the first embodiment.

FIG. 12 is a diagram showing measurement results of inclination angles of the through hole of Comparative Example 3 in the first embodiment.

FIG. 13 is a diagram showing SEM images of cross sections of the through holes of each Example and each Comparative Example in the second embodiment.

FIG. 14 is a diagram showing an example of a configuration of a multilayer wiring substrate in the second embodiment.

FIG. 15 is a diagram showing another example of a configuration of the multilayer wiring substrate in the second embodiment.

FIG. 16 is a diagram showing a step of preparing a glass substrate.

FIG. 17 is a diagram showing a step of forming laser modified portions.

FIG. 18 is a diagram showing a step of forming through holes.

FIG. 19 is a diagram showing a step of forming through electrodes in each through hole.

FIG. 20 is a diagram showing a step of forming a first wiring layer and a second wiring layer.

FIG. 21 is a diagram showing a case in which a multilayer wiring substrate is used as an interposer substrate for a semiconductor device and a substrate.

FIG. 22 is a diagram showing a cross section in the case of FIG. 21.

FIG. 23 is a diagram showing a case in which the multilayer wiring substrate and the semiconductor device are used in an electronic device for communication.

FIG. 24 is a diagram showing a cross section in the case of FIG. 23.

### DESCRIPTION OF EMBODIMENTS

Hereinafter, glass multilayer wiring substrates with through electrodes according to each embodiment of the present invention will be described with reference to the drawings. The following embodiments and Examples are merely examples of the embodiments of the present invention, and the present invention is not intended to be construed as being limited to these embodiments and examples. In the drawings referred to in the embodiments of the present invention, the same or similar reference numerals and characters (reference signs each consisting of only A, B, or the like, added after the number) are used for the same portions, and repeated explanation may be omitted. In addition, the description of the dimensions and ratios in the drawings may differ from the actual ratios for the convenience, or may be omitted from some of the configurations.

The position, size, shape, range, or the like of each component shown in the drawings may not represent the actual position, size, shape, range, and the like, in order to make the invention easier to understand. For this reason, the present invention is not necessarily limited to the position, size, shape, range, and the like disclosed in the drawings.

In the present disclosure, the term “surface” may refer not only to the surface of a plate-like member, but also to the interface of a layer contained in a plate-like member that is substantially parallel to the surface of the plate-like member. Additionally, “upper surface” or “lower surface” means the surface shown on the upper side or lower side on a drawing when a plate-like member or a layer contained in a plate-like member is illustrated. The “upper surface” and the “lower surface” are sometimes referred to as a “first surface” and a “second surface”.

A term “side surface” means a thickness portion of a surface or a layer in a plate-like member or a layer contained in a plate-like member. Part of a surface and a side surface may be collectively referred to as an “end portion”.

A “side surface of a through hole” means the interface between an object and an opening.

An “upper side” means a vertically upward direction when a plate-like member or a layer is placed horizontally. An “upper side” and a “lower side” opposite to this are sometimes referred to as a “positive Z-axis direction” and a “negative Z-axis direction”, and a horizontal direction is sometimes referred to as an “X-axis direction” and a “Y-axis direction”.

A distance in the Z-axis direction is referred to as a “height,” and a distance on an XY plane defined by the X-axis and Y-axis directions is referred to as a “width.” In referring to a layered object, the height is also referred to as a “thickness.”

A “through electrode provided in a glass substrate” means a conductive path provided for electrical continuity between the first surface and the second surface of the glass substrate when the glass substrate is used as part of a multilayer wiring substrate, and does not necessarily need to completely penetrate the glass substrate with a single conductive material. As long as the conductive path from the first surface and the conductive path from the second surface are connected, they are included in the through electrodes. The form of the through electrode may be a filled type in which a through hole is filled with a conductive material, or a conformal type in which only the side wall portion of the through hole is covered with a conductive material (the through hole includes both bottomed and completely through holes).

A “planar shape” and a “planar view” mean the shape when a surface or layer is seen from above. A “cross-sectional shape” and a “cross-sectional view” mean the shape when a plate-like member or a layer is cut in a specific direction and seen from the horizontal direction.

A “central portion” means the center portion, not a peripheral portion of the surface or the layer. A “center direction” means a direction from the peripheral portion of the surface or the layer toward the center in the planar shape of the surface or the Layer.

### Example

To describe Examples of a multilayer wiring substrate according to first and second embodiments of the present invention, the following shows a method for measuring inclination angles of a through hole 12 and a method for measuring a side surface roughness.

### (Method for Measuring Inclination Angles of Through Hole (X-Shape))

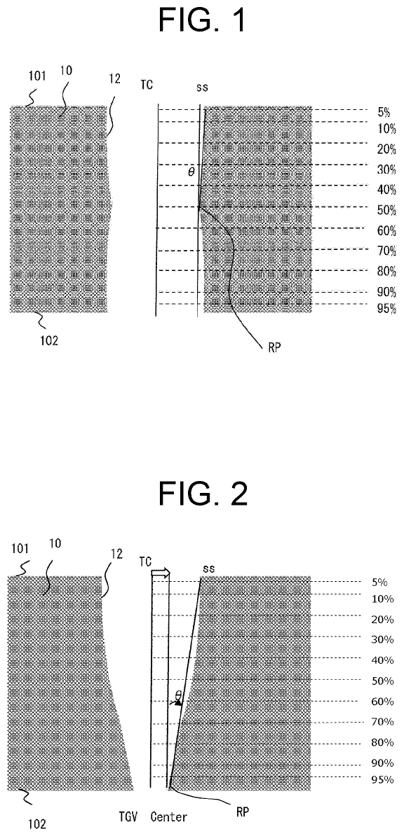

The following first describes a method for measuring the inclination angles in a shape of the through hole 12 obtained in the first embodiment of the present invention with reference to FIG. 1.

FIG. 1 is a diagram showing a cross section of the through hole 12 that has an hourglass shape (hereinafter also referred to as an “X-shape”) with a narrowed center in a height direction, and a method for measuring inclination angles. The cross section of the through hole 12 shown in FIG. 1 is obtained by dividing the through hole 12 from the first surface 101 side with a scriber to expose the cross section, and then performing image analysis on the SEM image observed with a SEM (Scanning Electron Microscope).

The cross section of the through hole 12 appears by dividing (cutting) the through hole 12 from the first surface 101 side in the thickness direction of the glass substrate with a scriber to expose a cross section (cut surface). As a method for dividing, for example, three-point bending can be applied. The exposed cross section is then observed with a SEM (Scanning Electron Microscope), and the SEM image is analyzed using image analysis software. Image analysis of the SEM image of the cross section allows the angles of the through hole 12 to be measured.

FIG. 1 shows the cross section taken along a plane passing through the center of the through hole 12, and the area shown with the pattern design indicates the glass substrate 10. The scale of 5%, 10%, . . . 95% shown in FIG. 1 each indicate a percentage with respect to a length from the first surface 101 of the glass substrate 10 to the second surface 102 thereof.

The shape of the through hole 12 shown in FIG. 1 has a structure that is almost symmetrical up and down at the position of scale 50%. In the method for measuring the inclination angles of the side surface of the through hole 12, a center line TC is drawn at a central portion of an opening on the first surface 101 side of the glass substrate 10 so as to be perpendicular to the first surface 101, in the section of 5% to 50% in distance from the first surface 101, as shown in FIG. 1.

Next, the center line TC is translated toward either sides of the through hole 12 and is brought into contact with the point where the diameter of the through hole 12 is at its minimum value, and the point of contact is set as a reference point RP. Then, tangents ss are drawn that are straight lines connecting the reference point RP to cross-sectional positions at heights of each of scale positions of 5% to 50%, and the inclination angles of each tangent ss are measured and defined as the inclination angles at each of the cross-sectional positions of 5% to 50%. The inclination angle is positive in the direction in which the diameter of the through hole 12 expands either upward or downward.

Similarly, in the section of 50% to 95% in distance from the first surface 101, a center line TC is drawn at a central portion of the opening on the second surface 102 side of the glass substrate 10 so as to be perpendicular to the second surface 102. Next, the center line TC is translated toward either side of the through hole 12, and is brought into contact with the point where the diameter of the through hole 12 is at its minimum value, and the point of contact is set as the reference point RP. Then, tangents ss are drawn from the reference point RP to the cross-sectional positions at the heights of each of the scale positions of 50% to 95%, and the inclination angles of the tangents ss are measured.

### (Method for Measuring Inclination Angles of Through Hole (Truncated Cone Shape))

Next, the shape of the through hole 12 obtained in the second embodiment of the present invention will be described with reference to FIG. 2. FIG. 2 is a diagram showing a cross section of the truncated cone-shaped through hole 12 and a method for measuring inclination angles. The cross section of the through hole 12 shown in FIG. 2 appears by dividing (cutting) the through hole 12 from the first surface 101 side in the thickness direction of the glass substrate with a scriber to expose a cross section (cut surface). As a method for dividing, for example, three-point bending can be applied. The exposed cross section is then observed with a SEM (Scanning Electron Microscope), and the SEM image is analyzed using image analysis software. Image analysis of the SEM image of the cross section allows the angles of the through hole 12 to be measured.

The through hole 12 shown in FIG. 2 has a truncated cone shape, and the through hole 12 has a minimum value on a second surface 102 side at which the diameter of the through hole is minimum. The scales of 5%, 10%, . . . 95% shown in FIG. 2 each indicate a percentage with respect to the length from the first surface 101 of the glass substrate 10 to the second surface 102 thereof.

A center line TC is drawn at a central portion of an opening on the second surface 102 side of the glass substrate 10 so as to be perpendicular to the second surface 102. Next, as shown by an arrow, the center line TC is translated toward either side of the through hole 12, the translated center line TC is brought into contact with the point where the diameter of the through hole 12 is at its minimum value, and the point of contact is set as a reference point RP. Then, tangents ss are drawn from the reference point RP to the cross-sectional positions at heights of each of the scale positions of 5% to 95%, and the inclination angles of each tangent ss are measured and defined as the inclination angles at each of the cross-sectional positions of 5% to 95%. The inclination angle is positive in a direction in which the diameter of the through hole 12 expands upward.

As described above, in the first and second embodiments, the method for measuring the inclination angles includes the following protocols of (1) to (3): (1) creating a center line of the through hole 12; (2) moving the center line horizontally to the position of the minimum value to create a reference point; and (3) drawing tangents from the reference point to each position and measuring their angles. In particular, employing the protocol of (2) creating a reference point enables a highly reliable measurement while a scale is satisfied that overlooks the entire through hole and that is not affected by fine unevenness on the side wall.

### (Method for Measuring Side Surface Roughness)

The following describes a method for measuring a side surface roughness of the through hole 12 in the first and second embodiments. To measure the side surface roughness of the through hole 12, the cross section of the through hole 12 is observed by SEM, as in the measurement of the side surface angle, and the observed SEM image is analyzed using image analysis software. To measure the side surface roughness of the through hole, the measurement range is normally the range from the first surface 101 to the second surface 102 of the through hole. However, if there are projections and recesses in the through hole, two or more ranges excluding the parts of the projections and recesses are set as measurement ranges, and the results of these measurement ranges are averaged to determine the side surface roughness. In calculating the side surface roughness, the same measurements are made on five through holes (sample number n=5) created under the same conditions, and the average value is defined as the side surface roughness of the through hole created under the conditions.

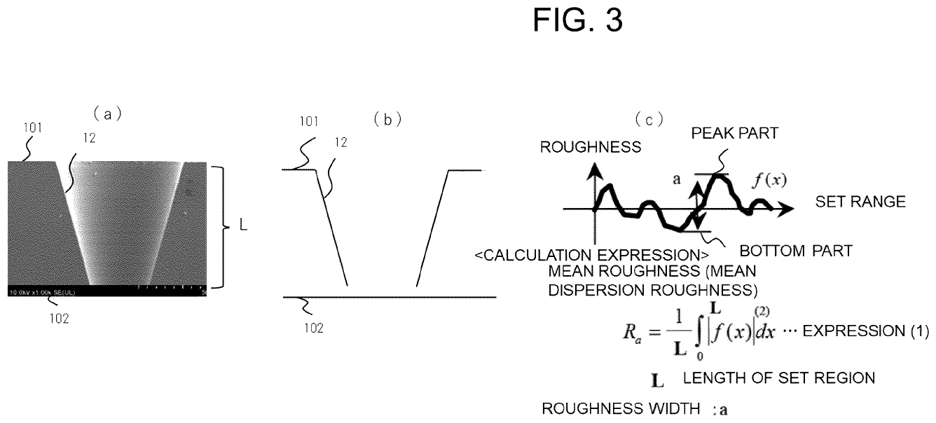

FIG. 3 is a diagram showing a method for measuring the side surface roughness of the through hole using an example of a truncated cone shape in the second embodiment. FIG. 3(a) shows a SEM image of the cross section of the through hole 12. FIG. 3(b) shows a diagram in which the contour of the side surface of the through hole 12 is extracted from the SEM image obtained by observation of the cross section of the through hole 12. The mean dispersion roughness and unevenness width are measured from the extracted contour data. FIG. 3(c) is a diagram schematically showing the calculation expression for the mean dispersion roughness and the unevenness width.

For the contour data extracted in FIG. 3(b), a roughness curve f(x) showing the roughness of the contour is measured in a set region L set based on the first surface 101. As shown in Expression (1), the mean dispersion roughness (hereinafter simply referred to as “dispersion roughness”) Ra is obtained by integrating the squared absolute value of a roughness curve f(x) over the set region L and then dividing it by the length of the set region L.

The roughness width (hereinafter also referred to as the “unevenness width”) a is the difference between the peak part showing the maximum roughness value and the bottom part showing the minimum roughness value of the roughness curve f(x).

When a plurality of roughness curves f(x) are set for one through hole, the average roughness of the through hole is calculated by averaging the roughness values calculated from them.

Such a method for measuring the side surface roughness is similar in the case of the X-shape.

### EXAMPLES AND COMPARATIVE EXAMPLES ACCORDING TO SECOND EMBODIMENT

The following describes a method for producing the through hole 12 in the second embodiment using FIG. 2. In the second embodiment, as shown in FIG. 18 described later, the glass substrate 10 in which laser modified portions 65 are formed is etched from both the first surface 101 and the second surface 102. As a result, the formed through holes 12 each have a minimum point where the diameter is smallest at a position approximately halfway between the first surface 101 and the second surface 102, and have a vertically symmetrical structure. The inclination angles of the side surface of the through hole 12 vary depending on the laser processing conditions and etching conditions for the glass substrate 10. In each Example, laser processing is performed under the irradiation conditions of the pulse width and number of shots shown in Table 1, and the through hole 12 is formed by etching.

In each Example of the present invention, the glass substrate is subjected to laser processing under the irradiation conditions of pulse width and number of shots shown in Table 1, and the through hole 12 is then formed by etching. In Example 1 of the second embodiment, the pulse width is 30 ps and the number of shots is 1, in Example 2 the pulse width is 30 ns and the number of shots is 100, and in Example 3 the pulse width is 50 us and the number of shots is 10.

In addition, the Comparative Examples are through holes created by changing the producing method and laser processing method shown in the second embodiment. In other words, in Comparative Example 1 the pulse width is 5 ps and the number of shots is 1, in Comparative Example 2 the pulse width is 15 ps and the number of shots is 1, and in Comparative Example 3 the pulse width is 15 ps and the number of shots is 1.

All of the Examples and Comparative Examples each had an average opening diameter of 80 μm on the second surface 102 side of the glass substrate 10, and had a 3σ of 4.5 μm or less in this case, the 30 being the average of the measured values plus three times the standard deviation. In addition, the formed laser modified portions 65 each had an opening diameter on the second surface 102, the opening diameter having a difference of 10 μm or less between its maximum opening diameter φMax and its minimum opening diameter φMin.

TABLE 1

| | Example | Example | Example | Comparative | Comparative | Comparative |
|---|---|---|---|---|---|---|
| | 1 | 2 | 3 | Example 1 | Example 2 | Example 3 |
| Pulse | 30 ps | 30 ns | 50 μs | 5 ps | 15 ps | 25 ps |
| width | | | | | | |
| Number | 1 | 100 | 10 | 1 | 1 | 1 |
| of shots | | | | | | |

### (Inclination Angle of Through Hole)

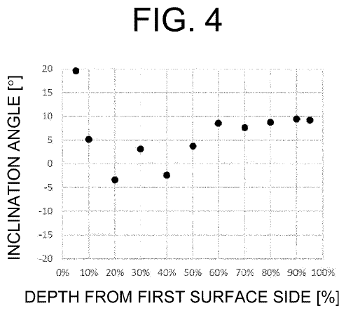

The following describes the shapes and characteristic shapes of the through holes of the Examples and Comparative Examples in the first and second embodiments with reference to FIGS. 4 to 12.

FIG. 4 is a diagram showing measurement results of inclination angles of a through hole of Example 1 in the second embodiment.

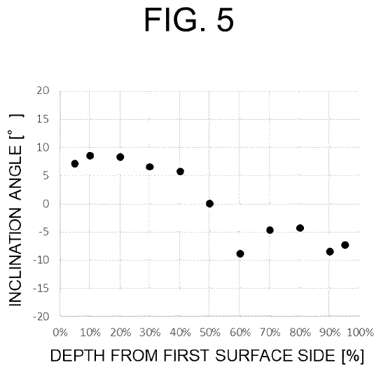

FIG. 5 is a diagram showing measurement results of inclination angles of a through hole of Example 2 in the second embodiment.

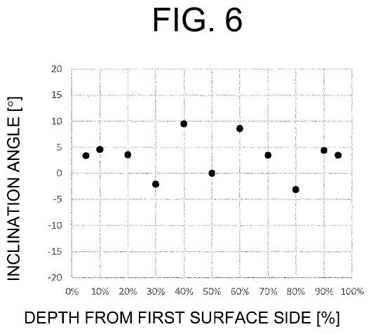

FIG. 6 is a diagram showing measurement results of inclination angles of a through hole of Example 3 in the second embodiment.

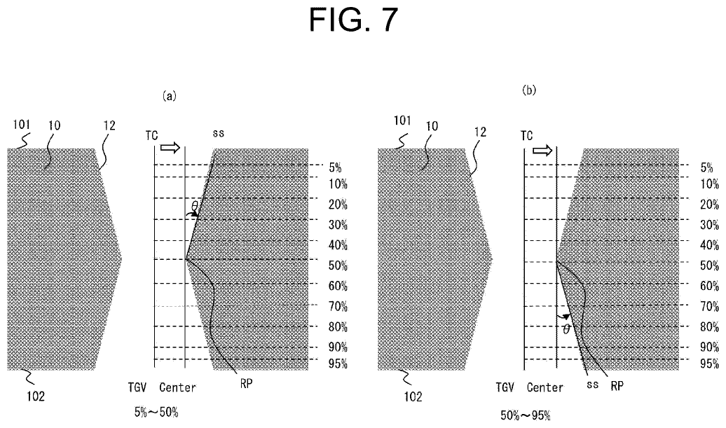

FIG. 7 is a diagram showing a cross-sectional shape of a through hole of Comparative Example 1 in the first embodiment.

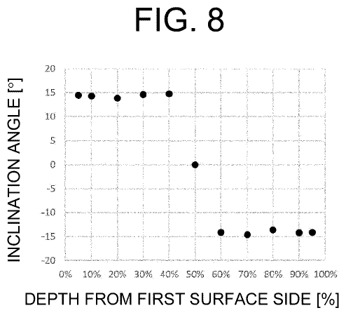

FIG. 8 is a diagram showing measurement results of inclination angles of the through hole of Comparative Example 1 in the first embodiment.

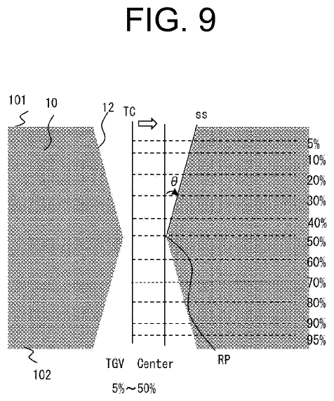

FIG. 9 is a diagram showing a cross-sectional shape of a through hole of Comparative Example 2 in the first embodiment.

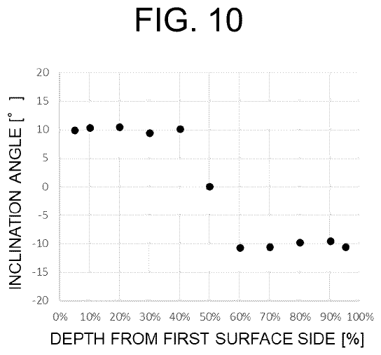

FIG. 10 is a diagram showing measurement results of inclination angles of the through hole of Comparative Example 2 in the first embodiment.

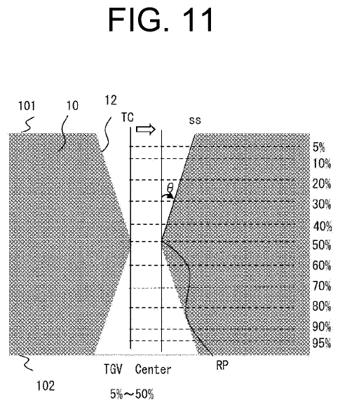

FIG. 11 is a diagram showing a cross-sectional shape of a through hole of Comparative Example 3 in the first embodiment.

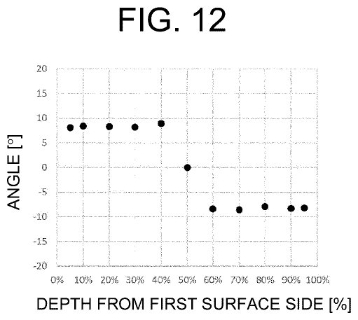

FIG. 12 is a diagram showing measurement results of inclination angles of the through hole of Comparative Example 3 in the first embodiment.

### (Inclination Angle)

Table 2 summarizes, in a tabular form, measurement results of the inclination angles of the side surfaces of the through holes 12 in each Example and each Comparative Example in the first embodiment. Each Example of the first embodiment demonstrates that the side surface inclination angles of the through hole 12 vary randomly. Each Comparative Example has a shape such that the lower half has the vertically reversed shape of the upper half with respect to the position at a distance 50% from the first surface 101, and has inclination angles varying less. In each Comparative Example, the randomly varied inclination angles allow the side surface of the through hole 12 to be stably roughened.

TABLE 2

| | Example | Example | Example | Comparative | Comparative | Comparative |
|---|---|---|---|---|---|---|
| | 1 | 2 | 3 | Example 1 | Example 2 | Example 3 |
| 5% | 7.1 | 3.4 | 19.6 | 14.5 | 9.8 | 8.1 |
| 10% | 8.5 | 4.6 | 5.1 | 14.3 | 10.3 | 8.4 |
| 20% | 8.3 | 3.6 | −3.4 | 13.9 | 10.4 | 8.3 |
| 30% | 6.5 | 2.1 | 3.1 | 14.6 | 9.4 | 8.2 |
| 40% | 5.7 | 9.5 | −2.4 | 14.8 | 10.1 | 8.9 |
| 50% | 0 | 0 | 3.7 | 0 | 0 | 0 |
| 60% | −8.9 | 8.6 | 8.5 | −14.1 | −10.8 | −8.4 |
| 70% | −4.7 | 3.5 | 7.6 | −14.6 | −10.6 | −8.6 |
| 80% | −4.3 | −3.1 | 8.7 | −13.6 | −9.9 | −7.9 |
| 90% | −8.5 | 4.4 | 9.4 | −14.2 | −9.6 | −8.3 |
| 95% | 7.4 | 3.5 | 9.2 | 14.1 | 10.6 | 8.2 |

### (Mean Dispersion Roughness and Unevenness Width)

Next, the mean dispersion roughnesses and unevenness widths of the side surfaces of the through holes 12 will be described with reference to Table 3 for each Example and each Comparative Example in the first embodiment. As shown in Table 3, each Example of the first embodiment has a dispersion roughness of 1,500 nm or more, and an unevenness width of 1,500 nm or more and 2,000 nm or less. Each Comparative Example has a dispersion roughness of 30 nm or more and 1,000 nm or less, and an unevenness width of 1,300 nm or less. These demonstrate that there is a difference in the roughnesses of the through hole side surfaces.

TABLE 3

| | Example | Example | Example | Comparative | Comparative | Comparative |
|---|---|---|---|---|---|---|
| | 1 | 2 | 3 | Example 1 | Example 2 | Example 3 |
| Dispersion | 1587.6 | 1685.3 | 1789.5 | 31.6 | 563.6 | 994.5 |
| roughness | nm | nm | nm | nm | nm | nm |
| Unevenness | 1659.1 | 1689.1 | 1985.4 | 354.6 | 1083.1 | 1294.5 |
| width | nm | nm | nm | nm | nm | nm |

### (Cross-Sectional Shape)

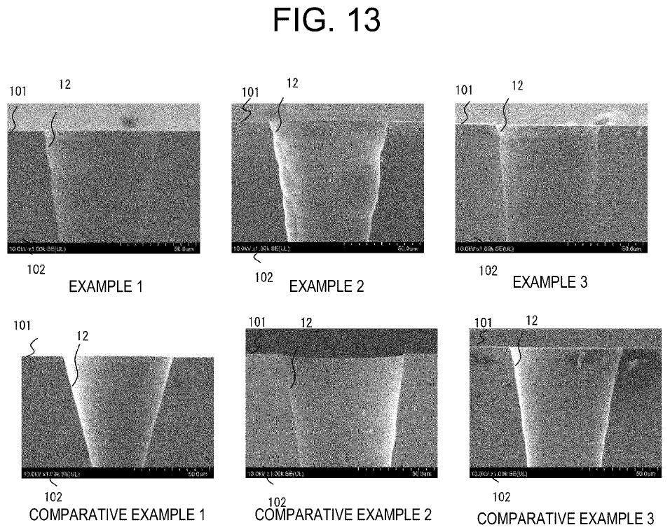

Next, the side surface shapes of the through holes 12 will be described. FIG. 13 is a diagram showing SEM images of cross sections of the through holes of each Example and each Comparative Example in the second embodiment. For Examples 1 to 3 and Comparative Examples 1 to 3 of the second embodiment, there were employed the same laser processing and etching conditions as the conditions for Examples 1 to 3 and Comparative Examples 1 to 3 of the first embodiment.

Note that as long as the laser processing and etching conditions are the same, the first embodiment has the same state of the cross section as the second embodiment, though there is a difference in whether the cross section is X-shaped or truncated cone-shaped.

Each SEM image is obtained by photographing the cut surface of a through hole in the thickness direction of the glass substrate. The SEM images shown in FIG. 13 are at a magnification of 1000 times (one division of the scale is 5 μm). In the SEM image, the areas that have high contrast and appear white are each a region where the inclined surface of the sample surface changes to form a ridgeline on the inclined surface. For this reason, the areas that appear as white lines each indicate either a peak or a bottom of the roughness on the sample surface, and placement of the ridgelines formed on the side surface of these through holes makes it possible to understand the roughness of the side surface of the through hole, which affects the adhesion of the through electrode.

Therefore, if the side surface of the through hole has a ridgeline whose absolute value of the inclination angle to the first surface is 45° or more, excellent adhesion of the through electrode can be obtained.

Furthermore, each Example of the second embodiment shown in FIG. 13 has fine unevenness formed in the diagonal direction and perpendicular direction to the first surface 101 of the glass substrate 10, and is formed with a scaly region.

Here, the scaly means having a plurality of closed regions each surrounded by ridgelines that can be seen. The closed region may be a region surrounded by a single ridgeline. For example, the closed region may be a closed region where a plurality of ridgelines overlap, or the closed region may have a different closed region and a ridgeline inside. For example, the closed region is 6 μm or more in the vertical direction and 4 μm or more in the horizontal direction.

Examples 1 to 3 each have a recessed portion of 20 μm² or more formed on the side surface of the through hole 12 due to fine unevenness occurring in the diagonal direction and the perpendicular direction to the first surface 101. The recessed portion creates an anchor effect for the conductor layer when the through electrode 11 is formed, making it possible to improve the adhesion between the conductive layer and the glass surface.

In addition, for the fine unevenness on the side surface of the through hole 12, the direction of the occurrence of fine unevenness and the area of the fine unevenness are measured from the cross-sectional SEM image using image processing software.

### (Via Pull Test Results for Through Electrodes)

The following describes the average strengths of the side surfaces of the through holes 12 in each Example and each Comparative Example using Table 4.

As shown in Table 4, the average strengths are measured by a via pull test. Here, the via pull test is a test to measure the tensile strength of a via by pulling the via, and the test conditions are as follows.
Test apparatus: DAGE Series 4000
Load cell: hot ball pull test (HBP)
Test speed: 5 μm/sec

In the via pull test, flux and solder are filled into the through electrode and a pin for strength measurement is then erected in the through electrode to measure the strength of the through hole 12. Then, the pin for measurement is pulled by a load cell to measure the strength of the glass substrate 10.

Note that for the flux, the solder, and the pin, materials may be appropriately selected depending on the diameter of the through hole 12.

As shown in Table 4, each Example has an average strength of 60 gf or more and 80 gf or less. Each Comparative Example has an average strength of 10 gf or more and 30 gf or less. These demonstrates that there is a difference in the average strengths of the through hole side surfaces.

TABLE 4

| | Example | Example | Example | Comparative | Comparative | Comparative |
|---|---|---|---|---|---|---|
| | 1 | 2 | 3 | Example 1 | Example 2 | Example 3 |
| Dispersion | 1587.6 | 1685.3 | 1789.5 | 31.6 | 563.6 | 994.5 |
| roughness | nm | nm | nm | nm | nm | nm |
| Unevenness | 1659.1 | 1689.1 | 1985.4 | 354.6 | 1083.1 | 1294.5 |
| width | nm | nm | nm | nm | nm | nm |
| Average | 65.6 | 69.3 | 70.2 | 10.1 | 19.2 | 23.2 |
| strength gf | | | | | | |

### Configuration of Multilayer Wiring Substrate According to First Embodiment

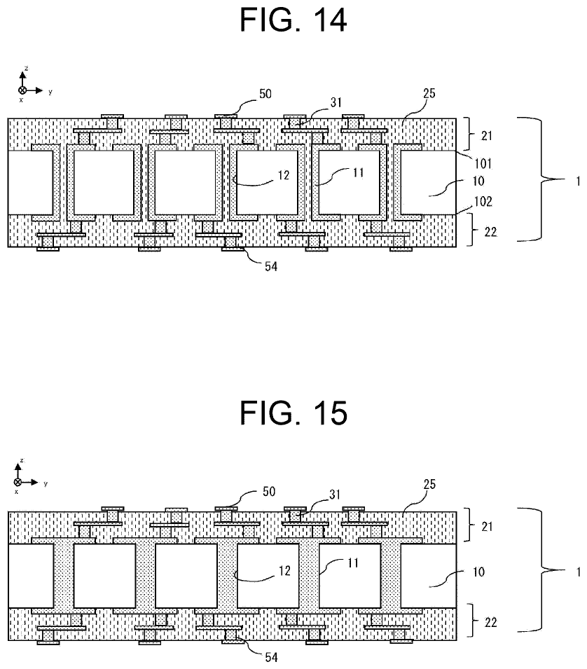

FIG. 14 is a diagram showing an example of a configuration of a multilayer wiring substrate 1 in the first embodiment. FIG. 15 is a diagram showing another example of a configuration of the multilayer wiring substrate 1 in the first embodiment.

A multilayer wiring substrate 1 includes a glass substrate 10, a first wiring layer 21, and a second wiring layer 22. The first wiring layer 21 is disposed on the first surface 101 side of the glass substrate 10, and the second wiring layer 22 is disposed on the second surface 102 side of the glass substrate 10. The glass substrate 10 includes the through holes 12 penetrating from the first surface 101 side to the second surface 102 side. Each through electrode 11 is formed of a conductor formed along the side surface of the through hole 12. The through electrode 11 electrically connects part of the first wiring layer 21 and part of the second wiring layer 22. The first wiring layer 21 and the second wiring layer 22 each include an insulating resin layer 25.

The first wiring layer 21 and the second wiring layer 22 may also be configured with a plurality of layers laminated, and the number of layers may be set as necessary. The through electrode 11 is an electrode for establishing an electrical connection between the first wiring layer 21 and the second wiring layer 22. The conductive electrodes 31 are each an electrode for ensuring electrical continuity in the thickness direction of the multilayer wiring substrate 1. Semiconductor power device joining pads 50 are members for connecting semiconductor circuits to be mounted on the multilayer wiring substrate 1. Substrate joining pads 54 are members for joining the multilayer wiring substrate 1 to another substrate or another semiconductor power device.

As long as the through electrode can electrically connect the first surface 101 side to the second surface 102 side of the glass substrate 10, a conductor may be disposed only on the side surface of the through hole 12 as shown in FIG. 14, or a conductor may be embedded in the through hole 12 as shown in FIG. 15.

Note that the shapes of the through holes 12 are shown with details omitted in FIGS. 14 and 15. Similarly, the detailed shapes thereof are omitted in FIGS. 18 to 20 described later. The specific shapes of each through hole 12 will be described using FIG. 13, and the roughnesses of each side surface of the through hole will be explained using an Example.

The thickness of the multilayer wiring substrate 1 is, for example, in a range of 100 μm to 400 μm inclusive.

### Method for Producing Multilayer Wiring Substrate in First Embodiment

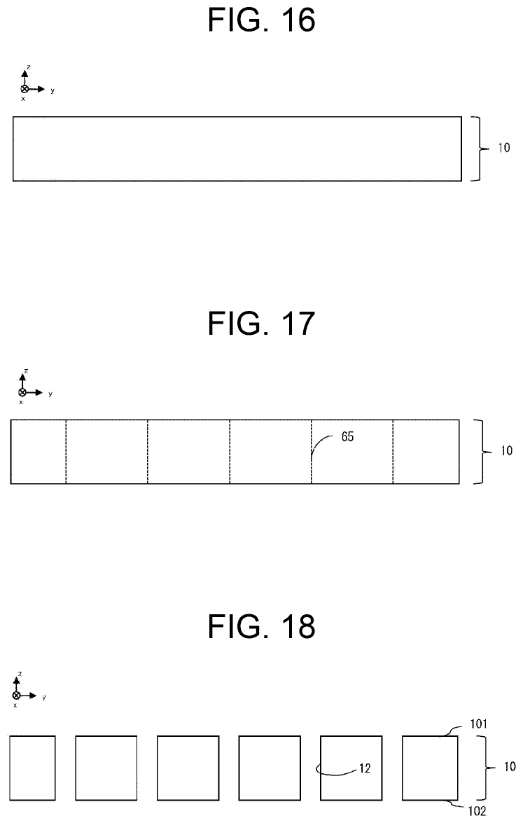

Next, a method for producing the multilayer wiring substrate 1 will be described using FIG. 16 to FIG. 20. First, a step of forming the through holes 12 in the glass substrate 10 will be described.

### [Glass Substrate]

FIG. 16 is a diagram showing a step of preparing the glass substrate 10. The thickness of the glass substrate 10 can be set appropriately depending on the application, taking into account the thickness of the glass substrate 10 after an etching step for forming the through holes.

The glass substrate 10 can use, for example, alkali-free glass with a SiO₂ ratio in a range of 55 mass % to 81 mass % inclusive. If the SiO₂ ratio of the glass substrate 10 is greater than 81 mass %, the processing rate of etching decreases, the flatness of the angle of the side surface of the through hole 12 decreases, and poor adhesion may occur in forming the through electrode 11, which will be described later. If the SiO₂ ratio is less than 55 mass %, alkali metals are highly likely to be contained in the glass, which will affect the reliability of the multilayer wiring substrate after the electronic device is mounted.

### [Laser Modification Step]

Next, FIG. 17 is a diagram showing a step of forming a laser modified portions (first step). Laser modified portions 65 are formed in the glass substrate 10 by irradiating the portions of the glass substrate 10 where through holes are to be formed with a laser. Each laser modified portion 65 is formed in the glass substrate 10 with a shape of Φ5 to 60 μm, and is formed continuously in the thickness direction of the glass substrate 10. At this time, when microcracks of 10 μm or more occur around the laser modified portion 65, the dispersion roughness of the side surface of the through hole 12 after etching will be 1,500 nm or more, and the unevenness width thereof will be 1,500 nm or more. This makes it possible to obtain the through hole 12 with a rough side surface.

When microcracks of 10 μm or more occur, the SEM image of the side surface of the through hole 12 after etching visibly shows not only the ridgelines extending in a direction parallel to the first surface 101 of the glass substrate 10, but also ridgelines extending in a direction perpendicular to the first surface 101 and ridgelines extending in a direction between the direction parallel to the first surface 101 and the direction perpendicular to the first surface 101, as is described later.

For processing the laser modified portion 65, it is preferable to use, for example, a picosecond to microsecond laser, and to use a laser emission wavelength of 1064 nm or 532 nm, or 355 nm. If the laser pulse width is 25 picoseconds or more, microcracks of 10 μm or more are likely to occur around the laser modified portion 65. For this reason, the laser pulse width is desirably 25 picoseconds or more. In addition, microcracks are likely to occur if processing is performed by a plurality of times of pulse irradiation.

### [Etching Step]

FIG. 18 is a diagram showing a step of forming the through holes (second step). The glass substrate 10 in which the laser modified portions 65 are formed is subjected to etching processing with a predetermined etching solution to form the through holes 12. At the same time, the first surface and the second surface of the glass substrate 10 are also etched, and the thickness of the glass substrate 10 decreases. When etching is performed from both the first surface 101 and the second surface 102 of the glass substrate 10, the through holes 12 of the first embodiment are processed to have a shape almost symmetrical up and down.

### [Etching Solution]

The etching solution to be used contains hydrofluoric acid in a range of 0.2 mass % to 20.0 mass % inclusive, nitric acid in a range of 4.0 mass % to 25.0 mass % inclusive, and inorganic acid other than hydrofluoric acid and nitric acid in a range of 0.5 mass % to 11.0 mass % inclusive. Examples of inorganic acids other than hydrofluoric acid and nitric acid include hydrochloric acid, sulfuric acid, phosphoric acid, and sulfamic acid. At least one inorganic acid is contained depending on the type of components other than silicon contained in the glass substrate 10. Desirably, the etching solution contains hydrochloric acid and sulfuric acid. The etching rate for the glass substrate 10 is appropriately adjusted to be in a range of 0.1 μm/min to 10 μm/min inclusive. The etching rate for the glass substrate 10 is desirably in a range of 0.25 μm/min to 4 μm/min inclusive, and more desirably in a range of 0.25 μm/min to 0.5 μm/min inclusive. The etching temperature is not particularly limited and can be adjusted appropriately, and is, for example, in a range of 10° C. to 30° C. inclusive.

### [Formation of Through Electrode]

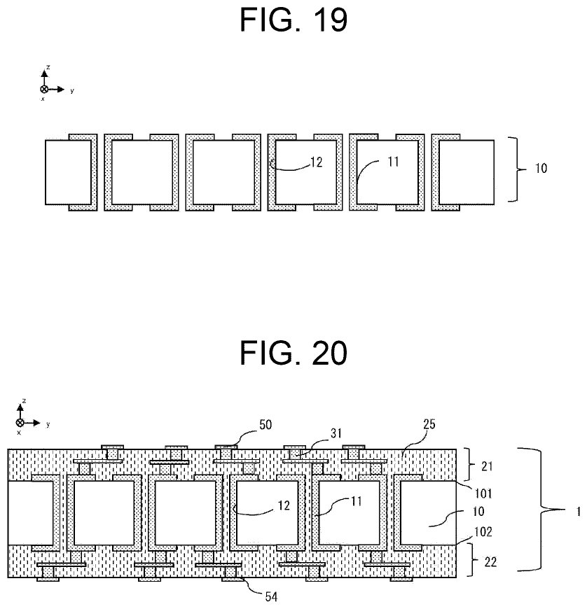

Next, FIG. 19 is a diagram showing a step of forming the through electrodes 11 in the through holes 12.

Metal layers for electrolytic plating processing is formed on the first surface 101 and the second surface 102 of the glass substrate 10 in which the through holes 12 are formed. The metal layer just needs to be made of any metal that functions as a seed layer for electrolytic plating processing, such as metals including Cu, Ti, Cr, W, Ni, or the like. The metal layer uses at least one of the above-mentioned metals. The metal layer desirably has a Cu layer formed on its outermost surface. Ti, Cr, W, and Ni are desirably used as an adhesion layer with the glass substrate 10 under the Cu layer. The thickness of the metal layer is appropriately set to a range that can cover the side surface of each through hole 12. The formation method to be employed can be, for example, a formation method through deposition using sputtering.

Subsequently, the through electrodes 11 are formed by electrolytic plating processing that uses the above-mentioned metal layer as the seed layer. To selectively grow the through holes 12, a mask is formed with an insulator such as a resist on the first surface 101 and the second surface 102 of the glass substrate 10 except for the through holes 12, and then electrolytic plating processing is performed. For a material to be used for electrolytic plating processing, for example, Cu can be used, and other metals including Au, Ag, Pt, Ni, Sn, or the like can also be used. Depending on the application of the multilayer wiring substrate, electrolytic plating processing may be performed so that the through holes 12 are filled with the above-mentioned metal conductors.

After electrolytic plating processing, the insulator such as a resist is removed, and the metal films formed on the first surface 101 and the second surface 102 of the glass substrate 10 are removed, so that the plurality of through electrodes 11 formed on the glass substrate 10 are electrically isolated from each other.

### [Formation of First Wiring Layer and Second Wiring Layer]

The following describes formation of the first wiring layer 21 and the second wiring layer 22 formed on the glass substrate 10 with reference to FIG. 20. FIG. 20 is a diagram showing a step of forming the first wiring layer 21 and the second wiring layer 22. For the glass substrate 10 on which the through electrodes 11 are formed, the first wiring layer 21 is formed on the first surface 101, and the second wiring layer 22 is formed on the second surface 102. In the step of forming the first wiring layer 21 and the second wiring layer 22, a mask having a pattern is first formed with a photosensitive resist or a dry film resist, and wiring is then formed by electrolytic plating processing. After that, physical adhesion processing or chemical adhesion processing is performed, and then the insulating resin layer 25 is laminated. For the conductive electrodes 31, holes are formed in the insulating resin layer 25 by laser processing or the like, and then a metal film is formed by electroless plating or deposition processing by sputtering. A mask having a pattern is formed on the above-mentioned metal film using resist, and the holes formed by electrolytic plating are filled with a conductor. The mask and excess metal film are then removed. The above-mentioned step is repeated a plurality of times depending on the number of layers required, to form the first wiring layer 21 and the second wiring layer 22. Note that the first wiring layer 21 and the second wiring layer 22 desirably have the same number of layers in order to prevent warping of the multilayer wiring substrate 1. If the layer thicknesses of the first wiring layer 21 and the second wiring layer 22 are different, the number of layers may be different between the first wiring layer 21 and the second wiring layer 22. The number of layers of the first wiring layer 21 and the number of layers of the second wiring layer 22 may be set appropriately depending on the application of the multilayer wiring substrate.

### [Formation of Insulating Resin Layer]

The insulating resin layer 25 is made of thermosetting resin. The material is, for example, a material that contains at least one of epoxy resin, polyimide resin, and polyamide resin, and that contains silica SiO₂ filler. The material is a liquid or film-like material. In the case of liquid resin, a spin coating method is used. In the case of film-like resin, a vacuum laminator is used. In any case, heating and pressurization are performed under vacuum to form the insulating resin layer 25. The material of the insulating resin layer 25 can be appropriately selected as necessary. However, when a photosensitive insulating resin material is used, filling the silica SiO₂ filler is difficult for ensuring photolithography properties. For this reason, a photosensitive insulating resin material can also be used, but it is more preferable to use thermosetting resin.

### Actions and Effects

As described above, according to this embodiment, the side surface of the through hole 12 can be stably formed to be rough, and this increases the frictional force against the surface with which the side surface of the through hole 12 comes into contact. This makes it possible to provide a glass substrate including a through electrode that has excellent adhesion.

### Third Embodiment

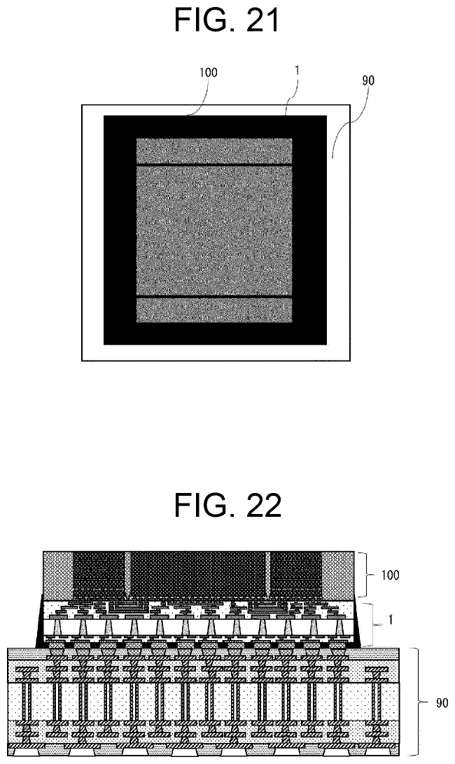

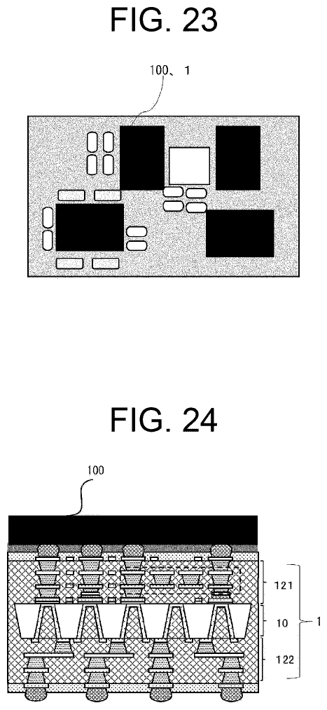

FIG. 21 is a diagram showing a case in which a multilayer wiring substrate 1 is used as an interposer substrate for a semiconductor power device 100 and a BGA (Ball Grid Array) substrate 90. FIG. 22 is a diagram showing a cross section of the case of FIG. 21. FIG. 23 is a diagram showing a case in which the multilayer wiring substrate 1 and the semiconductor power device 100 are used in an electronic device for communication. FIG. 24 is a diagram showing a cross section of the case of FIG. 23. The electronic device to be used has a layer thickness of 800 μm or less. For example, the electronic device is an interposer substrate on which a memory compatible with HBM (High Bandwidth Memory) is mounted.

The above-described electronic device has limited applications to which the device is adapted due to the effect of the transmission characteristics of the through electrodes, and the use of the glass multilayer wiring substrate with through electrodes of the present invention allows the electronic device to be adapted to a high frequency band region.

### Actions and Effects

As described above, according to this embodiment, the side surface of the through hole 12 can be stably formed to be rough, and this increases the frictional force against the surface with which the side surface of the through hole 12 comes into contact. This makes it possible to improve the adhesion of the through electrodes compared to existing techniques. Using the present invention enables providing a glass multilayer wiring substrate with through electrodes with excellent adhesion in a high frequency band.

The scope of the present invention is not limited to the exemplary embodiments illustrated and described, and includes various modified examples. For example, the above-mentioned embodiments are described in detail to describe the present invention in an easy-to-understand manner, and the scope of the present invention is not necessarily limited to those including all of the configurations described.

In addition, part of the configuration of one embodiment can be replaced with the configuration of another embodiment, and the configuration of another embodiment can be added to the configuration of one embodiment. In addition, part of the configuration of each embodiment can have another configuration added thereto, can be deleted, or can be replaced with another configuration.

Furthermore, all embodiments are also included that bring about an effect equivalent to the object of the present invention.

The present invention can also take the following aspects.

### (Aspect 1)

A glass substrate having a first surface and a second surface, the glass substrate comprising at least one through hole penetrating from the first surface to the second surface,
wherein a cross section of the through hole in a thickness direction of the glass substrate has a shape of a side surface, the shape having a dispersion roughness of 1,500 nm or more and an unevenness width of 1,500 nm or more.

### (Aspect 2)

A glass substrate having a first surface and a second surface, the glass substrate comprising at least one through hole penetrating from the first surface to the second surface,
wherein a SEM image of a cross section of the through hole in a thickness direction of the glass substrate allows a plurality of closed regions to be seen in a side surface of the through hole, the SEM image having a magnification of 1,000 times, each closed region being of 20 μm² and surrounded by a ridgeline.

### (Aspect 3)

The glass substrate according to Aspect 2, wherein the closed region surrounded by the ridgeline is 6 μm or more in a vertical direction and 4 μm or more in a horizontal direction.

### (Aspect 4)

The glass substrate according to any one of Aspects 1 to 3, wherein the side surface of the through hole has a ridgeline with an inclination angle having an absolute value of 45° or more to the first surface.

### (Aspect 5)

The glass substrate according to any one of Aspects 1 to 4, wherein an SiO₂ ratio of the glass substrate is in a range of 55 mass % to 81 mass % inclusive.

### (Aspect 6)

A multilayer wiring substrate including the glass substrate according to any one of Aspects 1 to 5, wherein
an electronic device mounted on the multilayer wiring substrate has a layer thickness of 800 μm or less, and
the multilayer wiring substrate has a thickness of 100 μm or more and 400 μm or less.

### (Aspect 7)

A method for producing a glass substrate having a first surface and a second surface, the glass substrate including at least one through hole penetrating from the first surface to the second surface, the method comprising:
a first step of irradiating a portion of the glass substrate with a laser to generate a microcrack in a range of 10 μm or less in a peripheral portion of laser irradiation, the portion of the glass substrate being where the through hole is to be formed;
a second step of etching the glass substrate irradiated with the laser to form the through hole.

### (Aspect 8)

The method for producing the glass substrate according to Aspect 7, wherein the laser radiated in the first step has any one of laser emission wavelengths of 1064 nm or more, 534 nm, and 355 nm, and has a pulse width of 30 picoseconds or more.

### REFERENCE SIGNS LIST

1: multilayer wiring substrate, 10: glass substrate, 11: through electrode, 12: through hole, 21: first wiring layer, 22: second wiring layer, 25: insulating resin layer, 31: conductive electrode, 50: semiconductor power device joining pad, 54: substrate joining pad, 65: laser modified portion, 90: BGA substrate, 100: semiconductor power device, 101: first surface of glass substrate 10, 102: second surface of glass substrate 10, TC: center line of through hole, ss: tangent to side surface of through hole

1. A glass substrate having a first surface and a second surface, the glass substrate comprising at least one through hole penetrating from the first surface to the second surface,
wherein a cross section of the through hole in a thickness direction of the glass substrate has a shape of a side surface, the shape having a dispersion roughness of 1,500 nm or more and an unevenness width of 1,500 nm or more.

2. A glass substrate having a first surface and a second surface, the glass substrate comprising at least one through hole penetrating from the first surface to the second surface,
wherein a SEM image of a cross section of the through hole in a thickness direction of the glass substrate allows a plurality of closed regions to be seen in a side surface of the through hole, the SEM image having a magnification of 1,000 times, each closed region being of 20 μm² and surrounded by a ridgeline.

3. The glass substrate according to claim 2, wherein the closed region surrounded by the ridgeline is 6 μm or more in a vertical direction and 4 μm or more in a horizontal direction.

4. The glass substrate according to claim 1, wherein the side surface of the through hole has a ridgeline with an inclination angle having an absolute value of 45° or more to the first surface.

5. The glass substrate according to claim 1, wherein an SiO₂ ratio of the glass substrate is in a range of 55 mass % to 81 mass % inclusive.

6. A multilayer wiring substrate including the glass substrate according to claim 1, wherein
an electronic device mounted on the multilayer wiring substrate has a layer thickness of 800 μm or less, and
the multilayer wiring substrate has a thickness of 100 μm or more and 400 μm or less.

7. A method for producing a glass substrate having a first surface and a second surface, the glass substrate including at least one through hole penetrating from the first surface to the second surface, the method comprising:
a first step of irradiating a portion of the glass substrate with a laser to generate a microcrack in a range of 10 μm or less in a peripheral portion of laser irradiation, the portion of the glass substrate being where the through hole is to be formed; and
a second step of etching the glass substrate irradiated with the laser to form the through hole.

8. The method for producing the glass substrate according to claim 7, wherein
the laser radiated in the first step has any one of laser emission wavelengths of 1064 nm or more, 534 nm, and 355 nm, and has a pulse width of 30 picoseconds or more.
